(19) United States
(12) Patent Application Publication
(10) Pub. No.: US 2019/0159338 A1
(43) Pub. Date: May 23, 2019

(54) ELECTRIC CIRCUIT INCLUDING A FLEXIBLE CONDUCTOR

(71) Applicant: SOLVAY SPECIALTY POLYMERS ITALY S.P.A., Bollate (IT)

(72) Inventors: Marco APOSTOLO, Senago (IT); Andrea Vittorio ORIANI, Bresso (IT); Stefano MAURI, Giussano (IT)

(21) Appl. No.: 16/321,462

(22) PCT Filed: Jul. 24, 2017
(86) PCT No.: PCT/EP2017/068595

§ 371 Date: Jan. 28, 2019

Related U.S. Application Data
(60) Provisional application No. 62/368,140, filed on Jul. 28, 2016.

(30) Foreign Application Priority Data
Aug. 30, 2016 (EP) 16186328.7

(51) Int. Cl. H05K 1/02; C23C 18/16; C23C 18/20; C23C 18/30; C23C 18/40; H01B 1/22; H05K 3/38

(52) U.S. Cl. CPC H05K 1/0283; C23C 18/1608; C23C 18/206; C23C 18/30; C23C 18/405; H05K 2201/0326; H05K 1/028; H05K 3/381; H05K 2201/0133; H05K 2201/0314; H01B 1/22

(57) ABSTRACT

The invention pertains to an electric circuit comprising a flexible conductor made from a metallized elastomer possessing electrical conductivity and ability to retain the same under strain/bending, to a method of conducting electrical current through said flexible conductor, to the use of the same as electro-conductive part in flexible displays, wearable electronics, conformable sensors and actuators, and to devices comprising the same.

### CROSS-REFERENCE TO RELATED APPLICATIONS

This application claims priority to U.S. provisional application No. 62/368,140 filed on Jul. 28, 2016 and to European application No. 16186328.7 filed on Aug. 30, 2016, the whole content of each of these applications being incorporated herein by reference for all purposes.

### TECHNICAL FIELD

The invention pertains to an electric circuit comprising a flexible conductor possessing electrical conductivity and ability to retain the same under strain/bending, to a method of conducting electrical current through said flexible conductor, to the use of the same as electro-conductive part in flexible displays, wearable electronics, conformable sensors and actuators, and to devices comprising the same.

### BACKGROUND ART

Streatchability and ability to retain electrical conductivity upon repeated cycles of bending are advantageous properties of flexible conductors, which would enable expanding dramatically fields of use of the same.

Indeed, electrically conductive materials are typically rigid materials, with inadequate mechanical resilience and which cannot withstand cycled or repeated stretching or bending phenomena.

Advances in this area have been driven by approaches wherein conductive active materials have been distributed in stretchable/bendable matrices: nevertheless, compatibility/processing limitations can significantly reduce the choice of supporting materials and limiting scope of variance in mechanical and electrical properties. As an alternative, patterning of nanomaterials on appropriate flexible substrates has been also pursued, although typical manufacturing techniques used, based on chemical vapour deposition and hence operating at high temperatures, somehow limit the choice of flexible materials used.

On the other side, metallized rubber parts are known. Notably, US 2007098978 3 May 2007 relates to a surface coated sealing material having chemical resistance, plasma resistance, and non-sticking while keeping strength, hardness, and sealing property of a rubber substrate, which comprises a coating film comprising one kind or more of metal or metallic compound selected from the group of metals, metal oxides, metal nitrides, metal carbides and compounds thereof on the whole or a part of the surface of the substrate which comprises a soft material, which can be a fluororubber. The coating film is manufactured on the rubber surface through a vacuum film forming process, such as ion plating process, sputtering process, CVD process, and a vacuum evaporation process. According to this document, the coated rubbers provided therein possess improved chemical and plasma resistance; their use in electrical and electrochemical devices is mentioned, but solely as sealing materials and/or as insulators. No mention is made therein of electrical conductivity.

Similarly, WO 2016/079230 (SOLVAY SPECIALTY POLYMERS ITALY SPA) 26 May 2016 relates to a multi-layered elastomer article made of an elastomeric composition comprising at least one elastomer, said article having at least one surface having nitrogen-containing groups and at least one layer adhered to said surface comprising at least one metal compound. The said assembly is manufactured through a two steps process including a nitrogen-plasma pre-treatment of the surface and a step of electroless plating comprising contacting the pre-treated surface with a metallization catalyst and then with a solution comprising a metal salt. Said multi-layer assemblies are described as providing electrical and thermal conductivity and a barrier to gases and liquids, and being able to withstand extreme environmental conditions due to chemical resistance, abrasion resistance and wear resistance, while maintaining its typical flexibility and mechanical properties. Nevertheless, the wide choice of metal compounds, thicknesses and processing parameters are not such to provide for flexible conductors possessing appropriate stretch-ability and electrical conductivity.

US 2014202744 (TOKAI RUBBER IND LTD) 24 Jul. 2014 discloses a conductive film formed from a conductive composition including an elastomer component, a fibrous carbon material, and a flake-like carbon material having a graphite structure.

### SUMMARY OF INVENTION

Thus, in a first aspect, the present invention relates to an electric circuit [circuit (E)] including at least one voltage generator and at least one flexible conductor [conductor (F)] made from an elastomeric composition [composition (C)] comprising at least one elastomer, said flexible conductor having at least one surface [surface (S)] comprising:
nitrogen-containing groups [groups (N)] on at least a portion of said surface (S); and
at least one layer [layer (L1)] adhered to at least said portion of said surface (S) having a thickness of at least 50 nm and of at most 1500 nm, and being made from at least one material selected from the group consisting of (i) metal compounds [compounds (M)] in zero oxidation state selected from the group consisting of metals possessing electrical conductivity of at least 10⁷ Siemens/m and (ii) metal oxides [compounds (MO)] selected from doped zinc oxide, doped copper/chromium oxide; possibly doped indium/tin oxides.

Yet, the invention further pertains to a method of conducting electrical current through a conductor (F), said method comprising submitting the conductor (F) as above detailed to at least one deformation.

Still another object of the invention is a method of making an electric device, preferably selected from the group consisting of flexible displays, wearable electronics, conformable sensors and actuators, comprising assembling the conductor (F), as above detailed, in an electrical circuit including at least a voltage generator.

The invention finally pertains to an electric device, preferably selected from the group consisting of flexible displays, wearable electronics, comprising at least one assembly including at least one conductor (F), as above detailed, and at least one voltage generator.

The Applicant has found that by proper choice of the metal and adaptation of the thickness it is possible to simultaneously achieve significant electric conductivity, while maintaining ability of the flexible conductor to be bended and stretched, so as to enable advantageous use of the same in all fields wherein the conductor is required to be deformed while conducting electrical current (for instance, an electrical signal, e.g. for a flexible display, in a conformable sensor, in an actuator, in wearable electronics.

Further, according to certain embodiments, the flexible conductor may be transparent, so that visible light can pass through the flexible conductor while at the same time the circuit of the invention enables conduction of electrical current under deformation of the said flexible conductor.

### BRIEF DESCRIPTION OF DRAWINGS

FIG. 1 is a graph showing resistance (in ohm) as a function of elongation (in %), as measured during deformation by extension (♦) or during recovery of original shape (□), for a flexible conductor in an electric circuit.

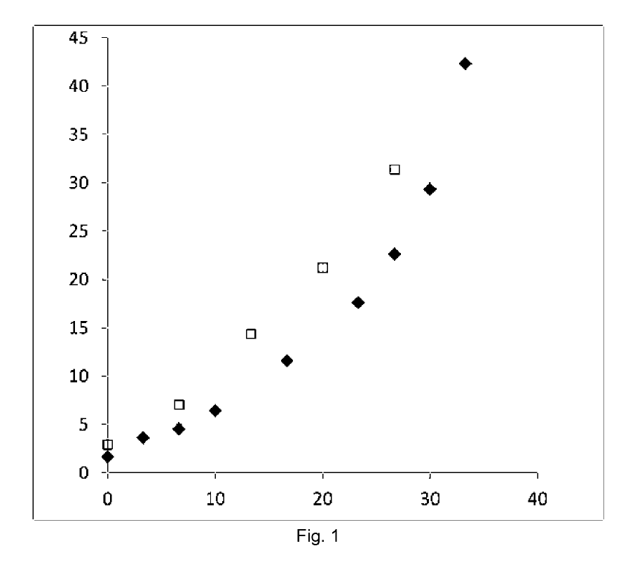

### DETAILED DESCRIPTION OF THE INVENTION

The Flexible Conductor

The flexible conductor of conductor (F), as above detailed, generally has an electrical conductivity substantially similar to the conductivity of compound (M) and/or compound (MO) of layer (L1). Hence, conductivity of conductor (F) can be adequately tuned by appropriate selection of compound (M) and/or compound (MO) to fit with the requirements of conductivity for being used in the circuit (E).

The conductor (F) comprises a layer (L1) made from one material selected from the group consisting of (i) metal compounds [compounds (M)] and (ii) metal oxides [compounds (MO)], as above detailed.

The expression “possibly doped indium/tin oxides” as used within the context of the present invention encompasses indium/tin mixed oxides and doped indium-tin mixed oxides.

The layer (L1) can extend on a portion of the surface (S) of the conductor (F) or may entirely coat said surface (S). According to certain embodiments, the conductor (F) may comprise said layer (L1) under the form of a pattern on the said portion of surface (S) comprising groups (N), as above detailed, advantageously defining at least a continuous path between at least two points of the said portion of surface (S), among which electrical current can circulate in the circuit (E).

In a preferred embodiment of the conductor (F), said groups (N) are grafted onto said surface (S). This is understood to mean that groups (N) are covalently bound to the polymer chains forming the surface (S) of the composition (C).

Without being bounded by any theory, the Applicant believes that at least part of said groups (N) grafted onto said surface (S) form chemical bonds with said at least one material selected from compounds (M) and (MO), thus obtaining an outstanding adhesion between at least said portion of surface (S) comprising groups (N) and said layer (L1) comprising compound (M) and/or (MO).

The expression “chemical bonds” is intended to indicate any type of chemical bond, such as for example covalent bond, ionic bond, dipolar (or coordinate) bond, between at least part of groups (N) grafted on the surface of the elastomer and compound (M) and/or (MO).

The term “elastomer” as used within the present description and in the following claims indicates amorphous polymers or polymers having a low degree of crystallinity (crystalline phase less than 20% by volume) and a glass transition temperature value (T_{g}), measured according to ASTM D3418, below room temperature. More preferably, the elastomer according to the present invention has a T_{g} below 5° C., even more preferably below 0° C.

Preferably, said elastomer comprises recurring units derived from at least one at least one (per)fluorinated monomer and/or at least one hydrogenated monomer; elastomer comprising said monomer(s) will be hereby referred as a (per)fluoro-elastomer. In a preferred embodiment, said monomers are free of nitrogen atoms.

By the expression “at least one (per)fluorinated monomer”, it is hereby intended to denote a polymer comprising recurring units derived from one or more than one (per)fluorinated monomers. In the rest of the text, the expression “(per)fluorinated monomers” is understood, for the purposes of the present invention, both in the plural and the singular, that is to say that it denote both one or more than one fluorinated monomers as defined above. The prefix “(per)” in the expression “(per)fluorinated monomer” and in the term “(per)fluoroelastomer” means that the monomer or the elastomer can be fully or partially fluorinated.

Non limitative examples of suitable (per)fluorinated monomers include, notably, the followings:
C₃-C₈ perfluoroolefins, such as tetrafluoroethylene (TFE) and hexafluoropropene (HFP);
C₂-C₈ hydrogenated fluoroolefins, such as vinylidene fluoride (VDF), vinyl fluoride, 1,2-difluoroethylene and trifluoroethylene (TrFE);
chloro- and/or bromo- and/or iodo-C₂-C₆ fluoroolefins, such as chlorotrifluoroethylene (CTFE);
CH₂═CH—R_{f0} wherein R_{f0} is a C₁-C₆ (per)fluoroalkyl or a C₁-C₆ (per)fluorooxyalkyl having one or more ether groups;
CH₂═CFOR_{f1}, wherein R_{f1} is a C₁-C₆ fluoro- or perfluoroalkyl group, such as CF₃, C₂F₅, C₃F₇;
CF₂═CFOR_{f2}, wherein R_{f2} is a C₁-C₆ fluoro- or perfluoroalkyl group, such as CF₃, C₂F₅, C₃F₇; or a C₁-C₁₂ oxyalkyl or a C₁-C₁₂ (per)fluorooxyalkyl group comprising one or more ether groups, such as perfluoro-2-propoxy-propyl; or a group of formula —CF₂OR_{f3} in which R_{f3} is a C₁-C₆ fluoro- or perfluoroalkyl or a C₁-C₆ (per)fluorooxyalkyl group comprising one or more ether groups, such as —C₂F₅—O—CF₃;
CF₂═CFOR_{f4}, wherein R_{f4} is a C₁-C₁₂ alkyl or (per)fluoroalkyl group; a C₁-C₁₂ oxyalkyl; or a C₁-C₁₂ (per)fluorooxyalkyl; said R_{f4} comprising a carboxylic or sulfonic acid group, in its acid, acid halide or salt form;
fluorodioxoles, such as perfluorodioxoles;
fluorosilanes, such as CF₃—C₂H₄—Si(R_{f5})₃ or Ar—Si(R_{f5})₃ wherein each of R_{f5} is independently selected from Cl, C₁-C₃ alkyl or C₁-C₃ alkoxy, and Ar is a phenyl ring optionally substituted with a C₁-C₆ fluoro- or perfluoroalkyl group, e.g. CF₃, C₂F₅, C₃F₇ or a C₁-C₆ (per)fluorooxyalkyl group comprising one or more ether groups, such as —C₂F₅—O—CF₃; and CH₂═CH₂—Si(R_{f6})₃ wherein each of R_{f6} is independently selected from H, F and C₁-C₃ alkyl, provided that at least one of said R_{f6} is F.

The expressions “at least one hydrogenated monomer” is intended to mean that the polymer may comprise recurring units derived from one or more than one hydrogenated monomers.

By the expression “hydrogenated monomer”, it is hereby intended to denote an ethylenically unsaturated monomer comprising at least one hydrogen atom and free from fluorine atoms.

Non limitative examples of suitable hydrogenated monomers include, notably, non-fluorinated monomers such as C₂-C₈ non-fluorinated olefins (OI), in particular C₂-C₈ non-fluorinated alpha-olefins (OI), including ethylene, propylene, 1-butene; diene monomers; vinyl monomers such as vinyl acetate and methyl-vinyl ether (MVE); acrylic monomers, like methyl methacrylate, butyl acrylate; styrene monomers, like styrene and p-methylstyrene; and silicon-containing monomers.

According to a preferred embodiment, said elastomer is a (per)fluoro-elastomer or a silicone elastomer.

Preferably, said (per)fluoro-elastomer has a T_{g} of less than 0° C., more preferably of less than −10° C., as measured as measured according to ASTM D-3418.

Typically, said (per)fluoro-elastomer comprises recurring units derived from the (per)fluorinated monomers cited above.

More preferably, said (per)fluoro-elastomer comprises recurring units derived from:
C₃-C₈ perfluoroolefins, such as tetrafluoroethylene (TFE) and hexafluoropropene (HFP);
C₂-C₈ hydrogenated fluoroolefins, such as vinylidene fluoride (VDF), vinyl fluoride, 1,2-difluoroethylene and trifluoroethylene (TrFE);
CF₂═CFOR_{f1}, wherein R_{f1} is a C₁-C₆ fluoro- or perfluoroalkyl group, such as CF₃, C₂F₅, C₃F₇, or a group of formula —CFOCF₂OR_{f2} wherein R_{f2} is a C₁-C₆ fluoro- or perfluoroalkyl group, e.g. CF₃, C₂F₅, C₃F₇;
fluorosilanes, such as CF₃—C₂H₄—Si(R_{f3})₃ wherein each of R_{f3} is independently selected from Cl, C₁-C₃ alkyl or C₁-C₃ alkoxy, and CH₂═CH₂—Si(R_{f4})₃ wherein each of R_{f4} is selected from H, F and C₁-C₃ alkyl.

Optionally, said (per)fluoroelastomer further comprises recurring units derived from at least one bis-olefin.

Non limiting examples of suitable bis-olefins are selected from those of formulae below:
R₁R₂C═CH—(CF₂)ⱼ—CH═CR₃R₄ wherein j is an integer between 2 and 10, preferably between 4 and 8, and R₁, R₂, R₃, R₄, equal or different from each other, are —H, —F or C₁-C₅ alkyl or (per)fluoroalkyl group;
A₂C═CB—O-E-O—CB═CA₂, wherein each of A, equal or different from each other, is independently selected from —F, —Cl, and —H; each of B, equal or different from each other is independently selected from —F, —Cl, —H and —ORB, wherein RB is a branched or straight chain alkyl radical which can be partially, substantially or completely fluorinated or chlorinated; E is a divalent group having 2 to 10 carbon atoms, optionally fluorinated, which may be inserted with ether linkages; preferably E is a —(CF₂)_{z}— group, with z being an integer from 3 to 5; and
R₆R₇C═CR₅-E-O—CB═CA₂, wherein E, A and B have the same meaning as above defined; R₅, R₆, R₇, equal or different from each other, are —H, —F or C₁-C₅ alkyl or fluoroalkyl group.

When a bis-olefin is employed, the resulting (per)fluoroelastomer typically comprises from 0.01% to 5% by moles of units deriving from the bis-olefin with respect to the total amount of units in the polymer.

Optionally, said (per)fluoroelastomer may comprise cure sites, either as pendant groups bonded to certain recurring units or as ends groups of the polymer chain, said cure sites comprising at least one iodine or bromine atom, more preferably at least one iodine atom.

Among cure-site containing recurring units, mention can be notably made of:

(CSM-1) iodine or bromine containing monomers of formula:

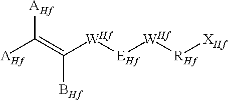

wherein each of A_{Hf}, equal to or different from each other and at each occurrence, is independently selected from F, Cl, and H; B_{Hf} is any of F, Cl, H and OR^{Hf}_{B}, wherein R^{Hf}_{B} is a branched or straight chain alkyl radical which can be partially, substantially or completely fluorinated or chlorinated; each of W^{Hf} equal to or different from each other and at each occurrence, is independently a covalent bond or an oxygen atom; E^{Hf} is a divalent group having 2 to 10 carbon atom, optionally fluorinated; R^{Hf} is a branched or straight chain alkyl radical, which can be partially, substantially or completely fluorinated; and R^{Hf} is a halogen atom selected from the group consisting of Iodine and Bromine; which may be inserted with ether linkages; preferably E is a —(CF₂)ₘ— group, with m being an integer from 3 to 5;

(CSM-2) ethylenically unsaturated compounds comprising cyanide groups, possibly fluorinated.

Among cure-site containing monomers of type (CSM1), preferred monomers are those selected from the group consisting of: (CSM1-A) iodine-containing perfluorovinylethers of formula:

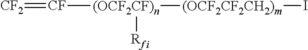

with m being an integer from 0 to 5 and n being an integer from 0 to 3, with the provisio that at least one of m and n is different from 0, and R_{fi} being F or CF₃; (as notably described in U.S. Pat. No. 4,745,165 (AUSIMONT SPA), U.S. Pat. No. 4,564,662 (MINNESOTA MINING) and EP 199138 (DAIKIN IND LTD); and

(CSM-1B) iodine-containing ethylenically unsaturated compounds of formula:

CX¹X²═CX³—(CF₂CF₂)ₚ—I

wherein each of X¹, X² and X³, equal to or different from each other, are independently H or F; and p is an integer from 1 to 5; among these compounds, mention can be made of CH₂═CHCF₂CF₂I, I(CF₂CF₂)₂CH═CH₂, ICF₂CF₂CF═CH₂, I(CF₂CF₂)₂CF═CH₂;

(CSM-1C) iodine-containing ethylenically unsaturated compounds of formula:

CHR═CH—Z—CH₂CHR—I

wherein R is H or CH₃, Z is a C₁-C₁₈ (per)fluoroalkylene radical, linear or branched, optionally containing one or more ether oxygen atoms, or a (per)fluoropolyoxyalkylene radical; among these compounds, mention can be made of CH₂═CH—(CF₂)₄CH₂CH₂I, CH₂═CH—(CF₂)₆CH₂CH₂I, CH₂═CH—(CF₂)₈CH₂CH₂I, CH₂═CH—(CF₂)₂CH₂CH₂I;

(CSM-1D) bromo and/or iodo alpha-olefins containing from 2 to 10 carbon atoms such as bromotrifluoroethylene or bromotetrafluorobutene described, for example, in U.S. Pat. No. 4,035,565 (DU PONT) or other compounds bromo and/or iodo alpha-olefins disclosed in U.S. Pat. No. 4,694,045 (DU PONT).

Among cure-site containing monomers of type (CSM2), preferred monomers are those selected from the group consisting of: (CSM2-A) perfluorovinyl ethers containing cyanide groups of formula CF₂═CF—(OCF₂CFX^{CN})ₘ—O—(CF₂)ₙ—CN, with X^{CN} being F or CF₃, m being 0, 1, 2, 3 or 4; n being an integer from 1 to 12;

(CSM2-B) perfluorovinyl ethers containing cyanide groups of formula CF₂═CF—(OCF₂CFX^{CN})_{m′}—O—CF₂—CF(CF₃)—CN, with X^{CN} being F or CF₃, m′ being 0, 1, 2, 3 or 4.

Specific examples of cure-site containing monomers of type CSM2-A and CSM2-B suitable to the purposes of the present invention are notably those described in U.S. Pat. No. 4,281,092 (DU PONT), U.S. Pat. No. 5,447,993 (DU PONT) and U.S. Pat. No. 5,789,489 (DU PONT).

Preferably, said (per)fluoroelastomer comprises iodine or bromine cure sites in an amount of 0.001 to 10% wt. Among these, iodine cure sites are those selected for maximizing curing rate, so that (per)fluoroelastomers comprising iodine cure-sites are preferred.

According to this embodiment, for ensuring acceptable reactivity it is generally understood that the content of iodine and/or bromine in the (per)fluoroelastomer should be of at least 0.05% wt, preferably of at least 0.1% weight, more preferably of at least 0.15% weight, with respect to the total weight of the (per)fluoroelastomer.

On the other side, amounts of iodine and/or bromine not exceeding preferably 7% wt, more specifically not exceeding 5% wt, or even not exceeding 4% wt, with respect to the total weight of the (per)fluoroelastomer, are those generally selected for avoiding side reactions and/or detrimental effects on thermal stability.

These iodine or bromine cure sites of these preferred embodiments of the invention might be comprised as pending groups bound to the backbone of the (per)fluoroelastomer polymer chain (by means of incorporation in the (per)fluoroelastomer chain of recurring units derived from monomers of (CSM-1) type, as above described, and preferably of monomers of (CSM-1A) to (CSM1-D), as above detailed) or might be comprised as terminal groups of said polymer chain.

According to a first embodiment, the iodine and/or bromine cure sites are comprised as pending groups bound to the backbone of the (per)fluoroelastomer polymer chain. The (per)fluoroelastomer according to this embodiment generally comprises recurring units derived from iodine or bromine containing monomers (CSM-1) in amounts of 0.05 to 5 mol per 100 mol of all other recurring units of the (per)fluoroelastomer, so as to advantageously ensure above mentioned iodine and/or bromine weight content.

According to a second preferred embodiment, the iodine and/or bromine cure sites are comprised as terminal groups of the (per)fluoroelastomer polymer chain; the fluoroelastomer according to this embodiment is generally obtained by addition to the polymerization medium during fluoroelastomer manufacture of anyone of:
iodinated and/or brominated chain-transfer agent(s); suitable chain-chain transfer agents are typically those of formula R_{f}(I)ₓ(Br)_{y}, in which R_{f} is a (per)fluoroalkyl or a (per)fluorochloroalkyl containing from 1 to 8 carbon atoms, while x and y are integers between 0 and 2, with 1≤x+y≤2 (see, for example, U.S. Pat. No. 4,243,770 (DAIKIN IND LTD) and U.S. Pat. No. 4,943,622 (NIPPON MEKTRON KK); and
alkali metal or alkaline-earth metal iodides and/or bromides, such as described notably in U.S. Pat. No. 5,173,553 (AUSIMONT SRL).

Among specific compositions of said (per)fluoro-elastomer, which are suitable for the purpose of the present invention, mention can be made of fluoroelastomers having the following compositions (in mol %):

(i) vinylidene fluoride (VDF) 35-85%, hexafluoropropene (HFP) 10-45%, tetrafluoroethylene (TFE) 0-30%, perfluoroalkyl vinyl ethers (PAVE) 0-15%, bis-olefin (OF) 0-5%;
(ii) vinylidene fluoride (VDF) 50-80%, perfluoroalkyl vinyl ethers (PAVE) 5-50%, tetrafluoroethylene (TFE) 0-20%, bis-olefin (OF) 0-5%;
(iii) vinylidene fluoride (VDF) 20-30%, C₂-C₈ non-fluorinated olefins (OI) 10-30%, hexafluoropropene (HFP) and/or perfluoroalkyl vinyl ethers (PAVE) 18-27%, tetrafluoroethylene (TFE) 10-30%, bis-olefin (OF) 0-5%;
(iv) tetrafluoroethylene (TFE) 50-80%, perfluoroalkyl vinyl ethers (PAVE) 20-50%, bis-olefin (OF) 0-5%;
(v) tetrafluoroethylene (TFE) 45-65%, C₂-C₈ non-fluorinated olefins (OI) 20-55%, vinylidene fluoride 0-30%, bis-olefin (OF) 0-5%;
(vi) tetrafluoroethylene (TFE) 32-60% mol %, C₂-C₈ non-fluorinated olefins (OI) 10-40%, perfluoroalkyl vinyl ethers (PAVE) 20-40%, fluorovinyl ethers (MOVE) 0-30%, bis-olefin (OF) 0-5%;
(vii) tetrafluoroethylene (TFE) 33-75%, perfluoroalkyl vinyl ethers (PAVE) 15-45%, vinylidene fluoride (VDF) 5-30%, hexafluoropropene HFP 0-30%, bis-olefin (OF) 0-5%;
(viii) vinylidene fluoride (VDF) 35-85%, fluorovinyl ethers (MOVE) 5-40%, perfluoroalkyl vinyl ethers (PAVE) 0-30%, tetrafluoroethylene (TFE) 0-40%, hexafluoropropene (HFP) 0-30%, bis-olefin (OF) 0-5%;
(ix) tetrafluoroethylene (TFE) 20-70%, fluorovinyl ethers (MOVE) 30-80%, perfluoroalkyl vinyl ethers (PAVE) 0-50%, bis-olefin (OF) 0-5%.

Suitable examples of (per)fluoroelastomers are the products sold by SOLVAY SPECIALTY POLYMERS S.p.A. under the trade name Tecnoflon®, such as for example Tecnoflon® PL 855.

Preferably, said silicone elastomer has a T_{g} of less than −10° C., more preferably of less than −30° C., and even more preferably of less than −50° C. as measured as measured according to ASTM D-3418.

Typically, said silicone elastomer comprises recurring units derived from silicon-containing monomers, and optionally further hydrogenated monomers and/or (per)fluorinated monomers as disclosed above.

By the expression “silicon-containing monomer”, it is hereby intended to denote a linear or branched monomer containing alternating silicon and oxygen atoms.

Non limitative examples of suitable silicon-containing monomers include:
silane, such as CH₂═CH₂—Si(R_{f7})₃ wherein each of R_{f7} is independently selected from H, F and C₁-C₃ alkyl;
siloxane of formula (R)₃Si—O—Si(R)₃ and (R)₂Si(OH)₂, wherein each R is independently selected from H, linear or branched alkyl groups having from 1 to 6 carbon atoms, preferably methyl group, or phenyl group.

Typically, said silicone elastomer is a polyorganosiloxane-based silicone rubber base, such as a polydimethyl siloxane containing crosslinking groups having hydroxyl, vinyl or hexenyl groups, or a polymethylphenyl siloxane.

Suitable examples of silicone elastomers are the products sold by Dow Corning Corp. (U.S.A.) under the trade name Silastic, such as Silastic 35U and Silastic TR-55 (dimethyl vinyl terminated, dimethyl organosiloxane).

Said groups (N) are not particularly limited, provided that they contain at least one nitrogen atom. Examples said of groups (N) are amino groups, amide groups, imino groups, nitrile groups, urethane groups and urea groups.

The thickness of said layer (L1) is of at least 50 nm, preferably of at least 75 nm and/or of at most 1500 nm, preferably at most 1000 nm, more preferably at most 500 nm.

When layer (L1) has a thickness of less than 50 nm, the electrical conductivity is not sufficient; when layer (L1) has a thickness of more than 1500 nm, the metallic layer becomes rigid and brittle, either impeding deformation, both in stretching or bending mode, and possibly undergoing cracking/failures responsible for loss of conductivity upon deformation.

The metal compound (M) comprises at least one metal selected from the group consisting of silver, copper, gold, aluminium, molybdenum, zinc, nickel, lithium, iron; and preferably comprises at least one metal selected from the group consisting of silver, copper, gold, and aluminium. According to certain embodiments, metal compound (M) may comprise more than one of the afore-mentioned metals, including under the form of alloys, such as e.g. brass Cu/Zn alloys.

The metal oxides [compounds (MO)] are selected from doped zinc oxide, doped copper (mixed) oxides; possibly doped indium/tin oxides.

Dopants for zinc oxide are advantageously selected from the group consisting of n-dopants, preferably selected from aluminium (yielding e.g. AZO), gallium (yielding e.g. GZO), sodium, magnesium, copper, silver, cadmium, indium (yielding e.g. IZO), tin, scandium yttrium, cobalt, manganese, chrome, and boron, and p-dopants, preferably selected from nitrogen, and phosphorous.

Among doped copper (mixed) oxides, mention can be made of copper oxides doped with at least one of sodium, magnesium, lithium, nickel, tin.

Compounds (MO) as above detailed can be used alone or in combination of a plurality of compounds (MO) or of a compound (MO) with another oxide.

The conductor (F), as above detailed, can be advantageously manufactured by a method comprising the steps of:

(i) providing an article made of an elastomeric composition [composition (C)] comprising at least one elastomer, said article having at least one surface [surface (S-1)];
(ii) forming nitrogen-containing groups [groups (N)] on at least a portion of said at least one surface (S-1) so as to provide an elastomer article having at least one nitrogen-containing surface portion [surface (S-2)];
(iii) contacting said at least one surface (S-2) with a first composition [composition (Cl)] comprising at least one metallization catalyst, so as to provide an article having at least one surface portion [surface (S-3)] containing groups (N) and at least one metallization catalyst; and
(iv) contacting said at least one surface (S-3) with a second composition [composition (C2)] containing at least one salt [compound (M1)] of a metal selected from the group of metals possessing electrical conductivity of at least 10⁷ Siemens/m, and/or with at least one precursor [compound (M2)] of a metal oxide (MO) as above detailed, in an amount and for a duration so as to provide a thickness of layer (L1) of at least 50 nm and of at most 1500 nm.

Under step (i) of the process of the present invention, said elastomeric composition (C) typically comprises at least one elastomer, for example in the form of slabs, powder, crumbs, liquids, gels; and further ingredients.

Suitable further ingredients and their amounts can be selected by the skilled person, depending on the type of elastomer used, the conditions used in the cross-linking step and/or the properties desired in the final article.

Typically, further ingredients can be selected from the following:
curing agents, such as polyhydroxylic compounds (for example Bisphenol A), triallyl-isocyanurate (TAIC) and organic peroxide (for example di-tertbutyl peroxide, 2,4-dichloro benzoyl peroxide, dibenzoyl peroxide, bis(1,1-diethylpropyl)peroxide, bis(1-ethyl-1-methylpropyl)peroxide, 1,1-diethylpropyl-1-ethyl-1-methylpropyl-peroxide, 2,5-dimethyl-2,5-bis(tert-amylperoxy)hexane, dicumyl peroxide, di-tert-butyl perbenzoate, bis[1,3-dimethyl-3-(tert-butylperoxy)butyl]carbonate and 2,5-bis(tert-butylper-oxy)-2,5-dimethylhexane, which is sold under the trade name Luperox®101XL45);
basic compounds, in particular bivalent metal oxides and/or hydroxide, such as MgO, ZnO and Ca(OH)₂; salts of a weak acid, such as Ba, Na, K, Pb, Ca stearate, benzoates, carbonates, oxalates, or phopshites; and mixtures thereof; and
conventional additives, in particular fillers, such as carbon black and fumed silica; accelerators, such as ammonium, phosphonium and aminophosphonium salt; thickeners; pigments; antioxideant; stabilizers; processing aids.

Preferably, in composition (C), said curing agents are in an amount of from 0.5 to 15 phr (i.e., parts by weight per 100 parts by weight of the elastomer), more preferably of from 2 to 10 phr.

Preferably, in composition (C), said basic compounds are in an amount of from 0.5 to 15 phr, more preferably of from 1 to 10 phr.

Preferably, in composition (C), said conventional additives are in an amount of from 0.5 to 50 phr, more preferably of from 3 to 40 phr.

Also, when the elastomer is a silicone elastomer, the composition (C) can further comprise an organosilane coupling agent, preferably in an amount of from 0.1 wt. % to 1.5 wt. % of said composition (C).

Said composition (C) is typically manufactured by using standard methods.

Typically, all the ingredients are first mixed together. Mixer devices such as internal mixers or open mill mixers can be used.

Under step (i) of the process of the present invention, said article is obtained by curing said composition (C).

The conditions for the curing of said composition (C) can be selected by the skilled person depending on the elastomer and the curing agent used.

For example, when the elastomer is a fluoroelastomer, curing can be performed at a temperature of from 100° C. to 250° C., preferably from 150° C. to 200° C., for a time of from 5 to 30 minutes.

Alternatively, when the elastomer is a silicone elastomer, curing can be performed at a temperature of from 100° C. to 200° C., for a time of from 5 to 15 minutes.

Preferably, in the method according to the present invention, said step (ii) is performed by treating said surface (S-1) in the presence of a nitrogen-containing gas.

Under step (ii) of the present invention, said nitrogen-containing gas is preferably selected from N₂, NH₃ or mixtures thereof, optionally in admixture with nitrogen-free gas such as CO₂ and/or H₂. More preferably, said nitrogen-containing gas is a mixture of N₂ and H₂.

The gas rate can be selected by the skilled person. Good results have been obtained by using gas flow between 5 nl/min and 15 nl/min, preferably of about 10 nl/min.

Preferably, said step (ii) is performed by an atmospheric plasma process.

Preferably, said atmospheric plasma process is performed under atmospheric pressure and with an equivalent corona dose of from 50 Wmin/m² to 30,000 Wmin/m², more preferably of from 500 Wmin/m² to 15000 Wmin/m².

Advantageously, said at least one surface (S-1) is continuously treated by said atmospheric plasma process in the presence of a nitrogen-containing gas, so as to provide a nitrogen-containing surface (S-2) providing outstanding adhesion with a layer (L1) comprising at least one metal compound, applied thereto as disclosed below.

In said step (ii), according to certain embodiments, screens and/or other patterning tools can be used for selectively treating at least a portion of the surface (S1), so as to selectively form groups (N), as above detailed, specifically on a portion of the said surface.

Preferably, under step (iii) of the present invention, said composition (C1) is in a solution or a colloidal suspension of the metallization catalyst in a suitable solvent, such as water.

Preferably, step (iii) is performed by dipping the elastomer as obtained in step (ii) in said composition (C1).

Preferably, compounds that may be employed as metallization catalysts in the method of the present invention are selected in the group comprising Pd, Pt, Rh, Ir, Ni, Cu, Ag and Au catalysts.

More preferably, the metallization catalyst is selected from Pd catalysts, such as PdCl₂.

Preferably, under step (iv), said composition (C2) is an electroless metallization plating bath, comprising at least one compound (M1), at least one reducing agent, at least one liquid medium and, optionally, one or more additives.

Preferably, said compound (M1) comprises one or more metal salts. More preferably, said compound (M1) preferably comprises one or more metal salts of the metals listed above with respect to compound (M).

Preferably, said reducing agent is selected from the group comprising formaldehyde, sodium hypophosphite, hydrazine, glycolic acid and glyoxylic acid.

Preferably, said liquid medium is selected from the group comprising water, organic solvents and ionic liquids.

Among organic solvents, alcohols are preferred such as ethanol.

Non-limitative examples of suitable ionic liquids include, notably, those comprising as cation a sulfonium ion or an imidazolium, pyridinium, pyrrolidinium or piperidinium ring, said ring being optionally substituted on the nitrogen atom, in particular by one or more alkyl groups with 1 to 8 carbon atoms, and on the carbon atoms, in particular by one or more alkyl groups with 1 to 30 carbon atoms.

Preferably, the ionic liquid is advantageously selected from those comprising as anion those chosen from halides anions, perfluorinated anions and borates.

Preferably, additives are selected from the group comprising salts, buffers and other materials suitable for enhancing stability of the catalyst in the liquid composition.

Preferably, said step (iv) is performed at a temperature above 30° C., for example between 40° C. and 50° C.

Preferably, said step (iv) is performed so as to provide a continuous layer (L1), which completely covers said surface (S), for example by dipping the elastomer as obtained in step (iii) in said composition (C2). However, depending on the application of the multi-layered article, said step (iv) may be performed so as to provide a discontinuous layer (L1), which partially covers said surface (S).

Preferably, said steps (iii) and (iv) are performed as a single step [step (iii-D)], more preferably by electroless deposition.

By “electroless deposition” it is meant a redox process typically carried out in a plating bath between a metal cation and a proper chemical reducing agent suitable for reducing said metal cation in its elemental state.

The preferred conditions disclosed above with respect to step (iii) and step (iv) apply whether steps (iii) and (iv) are performed separately or when step (iii) and step (iv) are performed as a single step (iii-D).

When use is made of a compound (M2), the said precursors of metal oxide (MO) can be selected from the group consisting of metal salts, metal hydroxides, and mixtures thereof. Deposition can be effected in different manners, including notably redox chemistry, neutralization, and the like.

According to certain embodiments, the conductor (F) may be a transparent conductor (F), i.e. a conductor wherein transmittance of incident visible light (in wave-lengths region of 400 to 700 nm) is of at least 60%, preferably 70%, even more preferably at least 75%, as determined as a ratio of intensity of incident light and intensity of transmitted light.

The Electric Circuit

As said, the electric circuit or circuit (E) of the present invention includes at least one voltage generator and at least one conductor (F), as above detailed.

One of ordinary skills in the art will select the most appropriate voltage generator, as a function of the specific intended field of use of the circuit (E). Direct current or alternating current voltage generator can be used, with constant or variable generated voltage. Any voltage generator able to convert a different form of energy (e.g. potential, kinetic . . . ) into electrical energy can be used.

For embodiments wherein the conductor (F) comprises said layer (L1) under the form of a pattern defining a continuous path between at least two points of the portion of its surface (S), the voltage generator is generally connected to the said points.

The electric circuit may comprise one or more than one additional components like resistors, capacitors, inductors, motors, outlet boxes, lights, switches, and other electrical and electronic components, which may be connected in different manner in the said circuit (E).

Generally, circuit (E) is conceived so that during its operations, electrical current generated by the voltage generator will flow through the conductor (F), as above detailed. During these operations, the conductor (F) may be submitted to deformations, such as bending and stretching, without its electrical performances being affected.

Method of Conducting Electrical Current

Hence, another object of the present invention is a method of conducting electrical current through a conductor (F) in a circuit (E), as above detailed, said method comprising submitting the conductor (F) to at least one deformation.

The Applicant has found that there is substantially no deformation hysteresis in the conductivity of the conductor (F), so that while conductivity of conductor (F) varies as a function of the deformation, recovery of initial shape and dimension will advantageously ensure recovery of substantially same conductivity as originally shown by the conductor (F).

According to this method, the conductor (F) possesses an original dimension and shape.

The deformation can be selected notably from elongation and bending.

In case of deformation by elongation, the conductor (F) is generally submitted to an axial tension force generating an elongation in the direction of said axis.

The conductor (F) is generally deformed by elongation in the direction of its axis parallel to the flow of electrical current at an elongation of at most 50%, preferably at least 40%, more preferably at least 35%, whereas elongation percentage is defined as the percent ratio of the dimension increase over the original dimension of the conductor (F).

In case of deformation by bending, the conductor (F) is generally submitted to a force in an orthogonal direction to at least a portion of the conductor (F) so as to force the conductor from a straight shape into a curved shape, or from a curved shape into a different shape.

Generally, the conductor is bent by applying forces in an orthogonal direction with respect to the flow of electrical current.

In case of a conductor (F) possessing a layer (L1) adhered to only one surface (S), bending can be applied either by deforming conductor (F) in a manner that said layer (L1) is adhered to a concave surface (hereby referred to as negative bending), or by deforming conductor (F) in a manner that said layer (L1) is adhered to a convex surface (hereby referred as positive bending).

Still another object of the invention is a method of making an electric device, preferably selected from the group consisting of flexible displays, wearable electronics, conformable sensors and actuators, comprising assembling the conductor (F), as above detailed, in a circuit (E) in said electric device.

The invention finally pertains to an electric device, preferably selected from the group consisting of flexible displays, wearable electronics, comprising at least one circuit (E) as above detailed.

Should the disclosure of any patents, patent applications and publications which are incorporated herein by reference conflict with the description of the present application to the extent that it may render a term unclear, the present description shall take precedence.

The present invention will be now described in more detail with reference to the following examples, whose purpose if merely illustrative and not limitative of the scope of the invention.

### Preparative Example 1—Manufacture of an Elastomer Article

The ingredients listed in the following Table 1 were mixed together in an open mill mixer.

TABLE 1

| | Amount |
|---|---|
| Ingredients | (phr) |
| Tecnoflon ® P757 fluoroelastomer (§) | 100 |
| N990 MT - Cancarb (#) | 30 |
| Luperox ® 101XL45 - Arkema (*) | 3 |
| Drimix TAIC 75 - Finco (\hat{ }) | 4 |

(§) Tecnoflon® P757 fluoroelastomer is a peroxide curable fluoroelastomer having Mooney viscosity measured at 120° C. according to ASTM D1646 of 21 MU, supplied by Solvay Specialty Polymers Italy S.p.A. (#) N990 MT is a carbon black grande supplied by Cancarb (*) 45% wt active dispersion of 2,5-dimethyl-2,5-di-t-butyl-peroxy-hexane in calcium carbonate; (̂) TAIC: Triallyl isocyanurate (75%) dispersion in silica, commercially available as Drimix TAIC 75 from Finco

The composition thus obtained was press-cured for 5 minutes at 170° C., so as to form plaques of 2 mm thick and 130 mm of side. The plaques were then post-cured in an oven (in air) for 4 hours at 230° C.

The plaques thus obtained were then cleaned with a lab cloth soaked with isopropyl alcohol (IPA), in order to remove dirt and contaminants.

### Preparative Example 2—Manufacture of a Flexible Conductor

Step 2(A)—Surface Activation

One of the surfaces of the molded plaques of elastomer parts of Example 1 was treated at atmospheric pressure by a radio-frequency plasma discharge process, using Plasmatreater® AS400 instrument. The etching gas was N₂. The working frequency was 20 kHz and the voltage was 0.3 kV.

Step 2(B)—Metallization Process after Cleaning

The treated surface of the specimen was coated with metallic copper by electroless plating, according to the procedure detailed hereunder.

The treated surface was first activated by immersion in an aqueous solution containing 0.03 g/L of PdCl₂ for 1 minute, in order to cover the sample surface with Palladium clusters.

Then, electroless deposition of copper was performed by dipping the sample in the bath containing Printogant PV solution (which is a commercial plating solution commercialized by Atotech, the main components of which are copper sulfate (CuSO₄), as source of copper ions, formaldehyde (HCHO), as reducing agent, sodium hydroxide (NaOH) as pH corrector, and a complexing agent to stabilize copper ions in solution) for 120 seconds, at 45° C., so that metallic copper was deposited on the surface of the plaque. The thickness of the copper layer coated onto the treated surface of the surface was 0.2 μm as measured by SEM.

Characterization of Electric Conductivity Performances of Circuits Including Flexible Conductor

Measurement of Resistance Vs Elongation

A 2 cm wide per 6 cm long specimen was cut from the flexible conductor sample obtained in Ex. 2. Two 4 mm wide copper strips were used as electric contacts on the sample, at a relative distance of 3 cm, and were connected to a digital multimeter so as to obtain a circuit.

The extremes of the specimen were clamped in frame with a fixed end and a movable crossbeam and tension was applied with an adjustable endless screw, so as to produce a variable elongation.

Resistance of the flexible conductor was measured using the digital multimeter at fixed deformation values during elongation. When 30% deformation was reached, the applied tension was gradually released and resistance values were measured at elongation values similar to those used during extension.

Table 2 below summarizes the results so obtained.

TABLE 2

| Linear Elongation | Resistance (Ω) | |
|---|---|---|
| 0.00% | 1.6 | Elongation |
| 3.33% | 3.6 | phase |
| 6.67% | 4.5 | |
| 10.00% | 6.4 | |
| 16.67% | 11.6 | |
| 23.33% | 17.6 | |
| 26.67% | 22.6 | |
| 30.00% | 29.3 | |
| 33.33% | 42.3 | |
| 26.67% | 31.4 | Tension |
| 20.00% | 21.2 | release |
| 13.33% | 14.3 | phase |
| 6.67% | 7 | |
| 0.00% | 2.9 | |

As data recollected above demonstrate, when the specimen was extended up to elongation values of exceeding 30%, the resistance of the flexible conductor underwent a moderate increase, while yet ensuring current to flow through the extended flexible conductor. This is of significance for demonstrating that the flexible conductor maintains appreciable electrical conductivity upon deformation. Further, when elongation was released and the specimen recovered the initial length, the resistance reverted substantially to the initial value. That's a clear indication that no irreversible phenomena occurred during the elongation phase and that the metal conductive layer was not damaged by this process.

Measurement of Resistance Vs Bending

A 2 cm wide per 6 cm long specimen was cut from the flexible conductor sample obtained in Ex. 2. Two 1 cm-wide adhesive flexible copper strips were used as electric contacts on the specimen, affixed at a relative distance of 3 cm, and connected to a digital multimeter voltage generator.

The specimen was therefore bended on non-conductive cylinders of known radius. “Negative” bending of the flexible conductor was obtained positioning the metallic surface facing/in contact with the cylinder surface. “Positive” bending of the flexible conductor was obtained positioning the elastomer surface facing/in contact with the cylinder surface.

Resistance of the flexible conductor was measured using the digital multimeter after bending on the said different cylinders

The following table describes resistance values measured at different bending radii.

TABLE 3

| Radius (cm) | Resistance (Ω) | |
|---|---|---|
| −1.5 | 6 | “negative |
| −3.0 | 8 | bending radii” |
| −5.5 | 11 | |
| flat | 12.5 | Flat |
| 5.5 | 19.5 | “positive |
| 3.0 | 98.5 | bending radii” |
| 1.5 | 222.5 | |

Data in table above confirms that also in the bending test the conductivity was substantially preserved, with no hysteresis phenomena.

1. An electric circuit (E) including at least one voltage generator and at least one flexible conductor (F) made from an elastomeric composition (C) comprising at least one elastomer, said conductor (F) having at least one surface (S) comprising:
nitrogen-containing groups (N) on at least a portion of said surface (S); and
at least one layer (L1) adhered to at least said portion of said surface (S) having a thickness of at least 50 nm and of at most 1500 nm, and being made from at least one material selected from the group consisting of (i) metal compounds (M) in zero oxidation state selected from the group consisting of metals possessing electrical conductivity of at least 10⁷ Siemens/m and (ii) metal oxide compounds (MO) selected from doped zinc oxide, doped copper/chromium oxide and doped indium/tin oxides.

2. The circuit (E) of claim 1, wherein the material is a metal compound (M) comprising at least one metal selected from the group consisting of silver, copper, gold, aluminium, molybdenum, zinc, nickel, lithium, and iron.

3. The circuit (E) of claim 1, wherein the material is a metal oxide selected from:
doped zinc oxides, wherein dopants are selected from the group consisting of n-dopants and p-dopants;
doped copper (mixed) oxides, selected from copper oxides doped with at least one of sodium, magnesium, lithium, nickel, tin; and
doped indium/tin oxides.

4. The circuit (E) of claim 1, wherein said elastomer is a (per)fluoro-elastomer having one of the following compositions (in mol %):
(i) vinylidene fluoride (VDF) 35-85%, hexafluoropropene (HFP) 10-45%, tetrafluoroethylene (TFE) 0-30%, perfluoroalkyl vinyl ethers (PAVE) 0-15%, bis-olefin (OF) 0-5%;
(ii) vinylidene fluoride (VDF) 50-80%, perfluoroalkyl vinyl ethers (PAVE) 5-50%, tetrafluoroethylene (TFE) 0-20%, bis-olefin (OF) 0-5%;
(iii) vinylidene fluoride (VDF) 20-30%, C₂-C₈ non-fluorinated olefins (OI) 10-30%, hexafluoropropene (HFP) and/or perfluoroalkyl vinyl ethers (PAVE) 18-27%, tetrafluoroethylene (TFE) 10-30%, bis-olefin (OF) 0-5%;
(iv) tetrafluoroethylene (TFE) 50-80%, perfluoroalkyl vinyl ethers (PAVE) 20-50%, bis-olefin (OF) 0-5%;
(v) tetrafluoroethylene (TFE) 45-65%, C₂-C₈ non-fluorinated olefins (OI) 20-55%, vinylidene fluoride 0-30%, bis-olefin (OF) 0-5%;
(vi) tetrafluoroethylene (TFE) 32-60% mol %, C₂-C₈ non-fluorinated olefins (OI) 10-40%, perfluoroalkyl vinyl ethers (PAVE) 20-40%, fluorovinyl ethers (MOVE) 0-30%, bis-olefin (OF) 0-5%;
(vii) tetrafluoroethylene (TFE) 33-75%, perfluoroalkyl vinyl ethers (PAVE) 15-45%, vinylidene fluoride (VDF) 5-30%, hexafluoropropene HFP 0-30%, bis-olefin (OF) 0-5%;
(viii) vinylidene fluoride (VDF) 35-85%, fluorovinyl ethers (MOVE) 5-40%, perfluoroalkyl vinyl ethers (PAVE) 0-30%, tetrafluoroethylene (TFE) 0-40%, hexafluoropropene (HFP) 0-30%, bis-olefin (OF) 0-5%; or
(ix) tetrafluoroethylene (TFE) 20-70%, fluorovinyl ethers (MOVE) 30-80%, perfluoroalkyl vinyl ethers (PAVE) 0-50%, bis-olefin (OF) 0-5%.

5. The circuit (E) of claim 1, wherein the conductor (F) is manufactured by a method comprising:
forming nitrogen-containing groups (N) on at least a portion of at least one surface (S-1) of an article so as to provide an elastomer article having at least one surface (S-2), wherein surface (S-2) is a nitrogen-containing surface portion, wherein the article has at least one surface (S-1) and is made of an elastomeric composition (C) comprising at least one elastomer;
contacting said at least one surface (S-2) with a first composition (C1) comprising at least one metallization catalyst, so as to provide an article having at least one surface (S-3), wherein surface (S-3) is a surface portion containing groups (N) and at least one metallization catalyst; and contacting said at least one surface (S-3) with a second composition (C2) containing at least one compound (M1), wherein compound (M1) is a salt of a metal selected from the group of metals possessing electrical conductivity of at least 10⁷ Siemens/m, and/or with at least one compound (M2), wherein compound (M2) is a precursor of the metal oxide compound (MO), in an amount and for a duration so as to provide a thickness of layer (L1) of at least 50 nm and of at most 1500 nm.

6. The circuit (E) according to claim 1, wherein the thickness of said layer (L1) of the conductor (F) is of at least 75 nm and/or of at most 1000 nm.

7. A method of conducting electrical current through at least one flexible conductor (F) made from an elastomeric composition (C) comprising at least one elastomer, said conductor (F) having at least one surface (S) comprising:
nitrogen-containing groups (N) on at least a portion of said surface (S); and
at least one layer (L1) adhered to at least said portion of said surface (S) having a thickness of at least 50 nm and of at most 1500 nm, and being made from at least one material selected from the group consisting of (i) metal compounds (M) in zero oxidation state selected from the group consisting of metals possessing electrical conductivity of at least 10⁷ Siemens/m and (ii) metal oxide compounds (MO) selected from doped zinc oxide, doped copper/chromium oxide and doped indium/tin oxides,
in an electrical circuit (E) including said conductor (F) and at least one voltage generator, said method comprising submitting said conductor (F) to at least one deformation.

8. The method of claim 7, wherein said deformation is an elongation wherein the conductor (F) is submitted to an axial tension force generating an elongation in the direction of said axis, generally in the direction of its axis parallel to the flow of electrical current.

9. The method of claim 7, wherein said deformation is a bending, wherein the conductor (F) is submitted to a force in an orthogonal direction to at least a portion of the conductor (F) so as to force the conductor from a straight shape into a curved shape, or from a curved shape into a different shape.

10. A method of making an electric device, the method comprising assembling at least one flexible conductor (F) made from an elastomeric composition (C) comprising at least one elastomer, said article having at least one surface (S) comprising:
nitrogen-containing groups (N) on at least a portion of said surface (S); and
at least one layer (L1) adhered to at least said portion of said surface (S) having a thickness of at least 50 nm and of at most 1500 nm, and being made from at least one material selected from the group consisting of (i) metal compounds (M) in zero oxidation state selected from the group consisting of metals possessing electrical conductivity of at least 10⁷ Siemens/m and (ii) metal oxide compounds (MO) selected from doped zinc oxide, doped copper/chromium oxide and doped indium/tin oxides in an electric circuit (E) comprising at least one voltage generator.

11. An electric device, comprising at least one electric circuit (E) including at least one flexible conductor (F) made from an elastomeric composition (C) comprising at least one elastomer, said article having at least one surface (S) comprising:
nitrogen-containing groups (N) on at least a portion of said surface (S); and
at least one layer (L1) adhered to at least said portion of said surface (S) having a thickness of at least 50 nm and of at most 1500 nm, and being made from at least one material selected from the group consisting of (i) metal compounds (M) in zero oxidation state selected from the group consisting of metals possessing electrical conductivity of at least 10⁷ Siemens/m and (ii) metal oxide compounds (MO) selected from doped zinc oxide, doped copper/chromium oxide and doped indium/tin oxides;
and at least one voltage generator.

12. The circuit (E) of claim 2, wherein the metal compound (M) comprises at least one metal selected from the group consisting of silver, copper, gold, and aluminium.

13. The circuit (E) of claim 3, wherein the n-dopants are selected from aluminium, gallium, sodium, magnesium, copper, silver, cadmium, indium, tin, scandium yttrium, cobalt, manganese, chrome, and boron.

14. The circuit (E) of claim 3, wherein the p-dopants are selected from nitrogen, and phosphorous.

15. The circuit (E) according to claim 6, wherein the thickness of said layer (L1) of the conductor (F) is of at most 500 nm.

16. The method of claim 9, wherein the conductor is bent by applying forces in an orthogonal direction with respect to the flow of electrical current.

17. The method of claim 10, wherein the electric device is selected from flexible displays, wearable electronics, conformable sensors and actuators.

18. The electric device of claim 11, wherein the electric device is selected from flexible displays and wearable electronics.
